(19) United States
(12) Patent Application Publication
(10) Pub. No.: US 2026/0221945 A1
(43) Pub. Date: Jul. 30, 2026

(54) LOW-NOISE AMPLIFIER

(71) Applicant: Taiwan Semiconductor Manufacturing Company, Ltd., Hsinchu (TW)

(72) Inventors: Yen-Jen Chen, Taipei City (TW); Kunai Mahaseth, Hsinchu (TW); Hsieh-Hung Hsieh, Taipei City (TW)

(21) Appl. No.: 19/265,494

(22) Filed: Jul. 10, 2025

Related U.S. Application Data
(60) Provisional application No. 63/749,363, filed on Jan. 24, 2025.

(51) Int. Cl. H03F 1/26; H03F 1/56; H03F 3/45

(52) U.S. Cl. CPC H03F 1/26; H03F 1/565; H03F 3/45179; H03F 2200/222; H03F 2200/294; H03F 2200/387; H03F 2200/451; H03F 2203/45024

(57) ABSTRACT

An amplifier circuit includes an input port, a first transistor and a second transistor that form a cascode topology. An output port is coupled to a first drain of the first transistor and a second drain of the second transistor. A first capacitor is coupled between the input port and a node. A first inductor is coupled between a gate bias voltage and the node, and a second inductor is coupled between the node and a first gate of the first transistor. A second capacitor is coupled between the node and a second gate of the second transistor. A resistor is coupled between the output port and the second gate of the second transistor.

### BACKGROUND

A Low Noise Amplifier (LNA) is often used in radio frequency (RF) circuits. The primary function of an LNA in an RF circuit is to amplify weak signals received by the antenna to levels suitable for processing by subsequent circuit stages while adding minimal noise and distortion. In the context of next-generation cellular applications, such as 5G networks, the role of the LNA becomes even more crucial due to the higher frequency bands and wider bandwidths involved. These applications require LNAs that can handle high-frequency signals with excellent linearity and low noise figures, ensuring that the integrity of the received signal is maintained, which is vital for achieving high data rate communications and efficient spectrum utilization.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. In addition, the drawings are illustrative as examples of embodiments of the invention and are not intended to be limiting.

FIG. 1 illustrates a block diagram schematically illustrating an RF system 200 including an LNA circuit.

FIG. 2 illustrates a low-noise amplifier (LNA) circuit that is implemented using a complementary, cascoding design in a differential mode.

FIG. 3 illustrates a differential LNA circuit with an example input matching network that is configured for wideband operation.

FIG. 4 illustrates a single ended LNA circuit with the example input matching network that is configured for wideband operation.

FIG. 5 illustrates a differential LNA circuit with the example input matching network and an example output matching network, both configured for wideband operations.

FIG. 6 illustrates a single ended LNA circuit with the example input matching network and the example output matching network both configured for wideband operations.

FIG. 7 illustrates a differential LNA circuit with the example input matching network that is configured for source degeneration and wideband operations.

FIG. 8 illustrates a differential LNA circuit with another example input matching network that is also configured for wideband operation.

FIG. 9 illustrates a single ended LNA circuit with the example input matching network that is configured for wideband operation.

FIG. 10 illustrates a differential LNA circuit with the example input matching network and an example output matching network, both configured for wideband operations.

FIG. 11 illustrates a single ended LNA circuit with the example input matching network and the example output matching network both configured for wideband operations.

FIG. 12 illustrates a differential LNA circuit with the example input matching network that is configured for source degeneration and wideband operations.

FIG. 13 illustrates the output performance of the differential LNA circuits from FIGS. 3 and 7.

FIG. 14 illustrates an example method 1400 of amplifying an RF signal using the LNA circuit from any of FIGS. 3-12.

FIG. 15 illustrates an example layout view of the differential LNA circuit with an example input matching network that is configured for wideband operation from FIG. 3.

FIG. 16 is a diagram 1600 schematically illustrating a cross-section of two example metal layer stacks used to implement an on-chip low-noise amplifier LNA circuit 104 of FIG. 1.

FIG. 17 illustrates a layout view of another example implementation of the inductors from an input matching network associated with an LNA circuit of FIG. 1.

FIG. 18 illustrates a layout view of an example vertical integration structure for implementing an on-chip LNA circuit, such as the LNA circuit from FIG. 1.

FIG. 19 illustrates an example flow chart diagram 1900 schematically illustrating a method of manufacturing a low-noise amplifier (LNA) circuit with an on-chip input matching network, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Low Noise Amplifiers (LNAs) are used in RF circuits, especially in cellular applications where they amplify weak signals received from antennas over various frequency bands. LNAs frequently utilize complementary metal oxide semiconductor (CMOS) technology and often adopt cascode structures, comprising two transistor stacks, to enhance gain, improve isolation, and minimize the Miller effect that can adversely impact bandwidth and stability. Achieving effective impedance matching is crucial in these circuits to minimize signal reflection and ensure maximum power transfer between stages and to subsequent components like mixers or filters. RF differential circuits, employed within these LNAs, help in maintaining impedance matching while also enhancing noise figure, linearity, and signal stability, which are pivotal in handling high data rates and complex modulation schemes in modern cellular communications.

Some LNA structures use a complementary circuit structure without inductors (i.e. an “inductorless” circuit structure). The gain of the LNA is derived from the transconductance (gm) and output resistance (rout) of NMOS and PMOS transistor pairs. The bandwidth is determined by the output resistance (R) and parasitic capacitance (C). However, RC roll-off constraints imposed by the output resistance and parasitic capacitance of the transistors presents significant challenges for wide bandwidth LNAs. The parasitic capacitance, an unwanted effect due to proximity between components within the circuit, restricts the high-frequency response, posing a substantial hurdle as operational frequencies increase.

The disclosed amplifier circuit incorporates specialized matching networks that optimize the interaction between the output resistance and parasitic capacitance, extending the amplifier's frequency range and making it suitable for the broad spectrum required in applications like sub-6 GHZ 5G systems. For example, the disclosed amplifier circuit includes shunt and/or series inductors in the specialized matching networks to achieve wideband operation.

The disclosed amplifier circuit not only focuses on enhancing bandwidth but also ensures robust performance across a range of frequencies and signal types, crucial for the aggregation of multiple frequency bands and the high-speed demands of modern cellular networks. By employing differential circuits and strategic matching networks, the disclosed amplifier circuit maintains high linearity and stability, ensuring that the amplifier meets the communication requirements of various cellular applications.

An advantage of the disclosed amplifier design is the integration of the matching network entirely on-chip, including both inductors and capacitors. Implementing the matching network within the die eliminates the need for discrete off-chip components, thereby reducing package-related parasitics, such as bond wire inductance and parasitic capacitance, which can degrade bandwidth and signal fidelity. On-chip integration also improves impedance control, simplifies assembly, and enables a more compact and scalable RF front-end design suitable for high-frequency and wideband applications.

To support this level of integration, the disclosed layout techniques strategically position inductive components in the top-most ultra-thick metal layers, while the active devices and interconnects are implemented in the lower and middle metal layers. This vertical separation minimizes substrate coupling and improves Q-factor by reducing resistive and dielectric losses. In some embodiments, the inductors may be implemented using dual ultra-thick metal (DUTM) technology, where two stacked copper layers (e.g., M9 and M10) further enhance inductive performance. In other configurations, transformer-based inductor layouts may be employed to conserve die area and improve magnetic coupling. Patterned ground shielding (PGS) may also be used beneath the inductors to suppress electromagnetic interference with underlying circuit elements. Together, these layout strategies enable high-performance, wideband operation while maintaining the integration density and signal integrity required for modern RF communication systems.

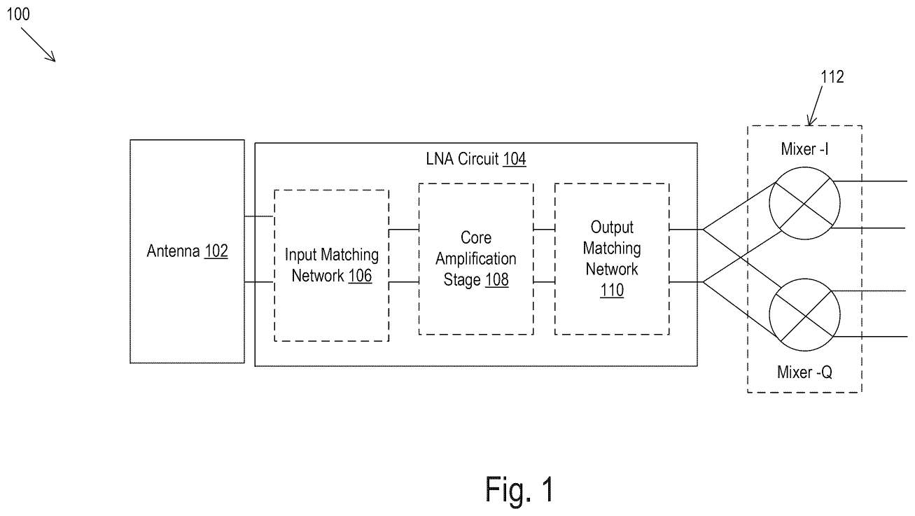

FIG. 1 illustrates a block diagram schematically illustrating an RF system 100. The RF system 100 is configured to efficiently amplify received RF signals while minimizing noise and maintaining signal integrity before further down-conversion and processing of the RF signals. In an example, the RF system 100 comprises an antenna 102, a LNA circuit 104 and a mixer module 110. In addition, the LNA circuit may include an input matching network 106 connected between the antenna 102 and a core amplification stage 108, and/or an output matching network 110 connected between the output of the core amplification stage 108 and an I/Q mixer module 112.

The antenna 102 is configured to receive incoming RF signals and may serve as the first stage of the signal reception path within the RF system 100. The RF signal from the antenna 102 may be processed by the input matching network 106 before being fed into the core amplification stage 108. The input matching network 106 is used to ensure impedance matching between the antenna and the input of the core amplification stage 108.

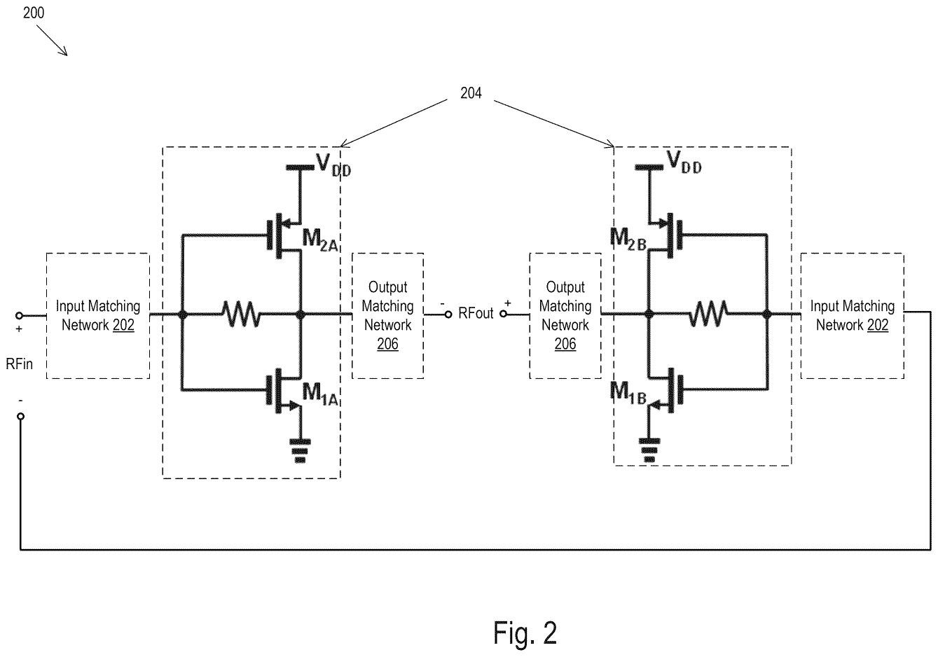

The core amplification stage 108 is configured to amplify the RF signal while minimizing noise introduce during amplification. In an example, the core amplification stage 108 is implemented using a cascoding differential design, described further in relation to FIG. 2. The amplified RF signal may be processed by an output matching network 110 before being transmitted to an I/Q mixer module 112, which consists of two mixer stages: Mixer-I and Mixer-Q. The I/Q mixer module 112 may be configured to perform frequency down-conversion by mixing the amplified RF signal with a local oscillator (LO) signal, generating intermediate frequency (IF) signals with in-phase (I) and quadrature (Q) components. These I/Q signals are subsequently used for demodulation and further signal processing in the RF system 100.

The input matching network 106 and the output matching network 110 are configured to provide impedance matching to minimize reflection losses, maximizing gain and to maintain a high signal-to-noise ratio within the RF system 100. In some examples, the input matching network 106 may be used without the output matching network 110. In other examples, both the input matching network 106 and the output matching network 110 may be used.

Although input and output matching circuits using discrete components are used in RF systems, the disclosed LNA circuit 104 integrates the input matching network 108 and the output matching network 110 that include a combination of series and shunt inductors and DC blocking capacitors as part of the integrated amplifier design. The resulting LNA design can be used in RF systems with a system on chip design and without needing to use discrete components to serve as matching networks.

FIG. 2 illustrates a low-noise amplifier (LNA) circuit 200 that includes an input matching network 202 connected to a core amplification stage 204, which itself is connected to an output matching network 206. The core amplification stage 204 of the LNA circuit 200 is implemented using a complementary, cascoding design in a differential mode. The LNA circuit 200 consists of a pair of NMOS transistors M1A, M1B and a pair of PMOS transistors M2A, M2B arranged in a differential configuration. The differential configuration of the amplifier ensures that the differential signals are amplified while suppressing common-mode noise and improving signal integrity.

In the LNA circuit 200, is configured to receive an input signal (RFin) at the gate terminals of the NMOS transistors M1A and M1B and the gate terminals of the PMOS transistors M2A and M2B. The source terminals of M1A and M1B are connected to a common ground. The drain terminals of M1A and M1B are coupled to the drain terminals of the PMOS transistors M2A, M2B, which serve as active loads. The PMOS transistors' M2A, M2B source terminals are connected to the supply voltage VDD. The drain terminals of the PMOS transistors M2A, M2B and the drain terminals of the NMOS transistors M1A, M1B are coupled to the output RFout. Further, bias resistors R1, R2 or an additional stabilization circuit may be connected between the gate terminals and drain terminals of the PMOS transistors M2A, M2B and NMOS transistors M1A, M1B to help set the DC operating point of the PMOS transistors M2A, M2B and to ensure that the gate voltage self-biases to the correct level by creating a feedback path that stabilizes the PMOS transistors M2A, M2B.

The operation of the LNA is based on the transconductance (gm) of the NMOS transistors M1A, M1B and the output resistance (rout) of the PMOS transistors M2A, M2B. When an input signal is applied at RFin, the NMOS transistors amplify the signal, with their gate-source voltage controlling the current flow. The PMOS transistors act as load devices, converting the amplified signal into an output voltage at RFout.

Generally in LNAs, the parasitic RC effects play a crucial role in determining the bandwidth, gain, and overall performance of the circuit. These effects arise due to intrinsic device properties, layout parasitics, and circuit topology. If not properly managed, RC parasitics can significantly degrade the high-frequency performance of the LNA.

The overall bandwidth of the LNA circuit 200 is determined by the output resistance and the parasitic capacitance at the drain terminals of M1A and M1B, forming an RC network that limits the frequency response. Thus, the LNA circuit 200 suffers from bandwidth constraints due to RC roll-off, making it less suitable for modern wideband RF applications.

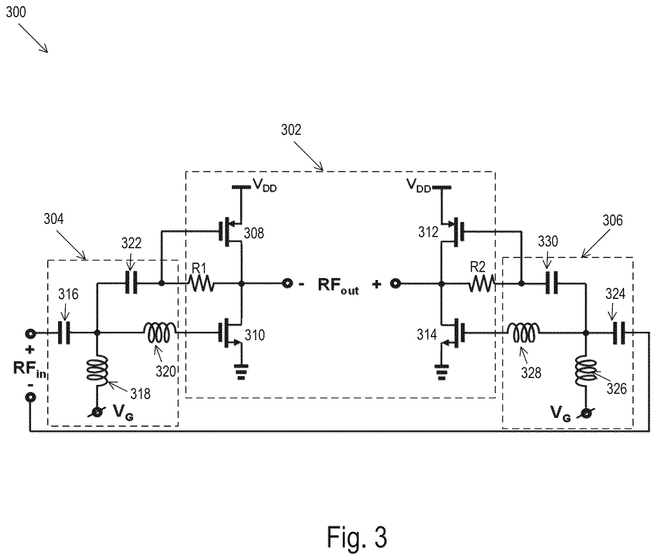

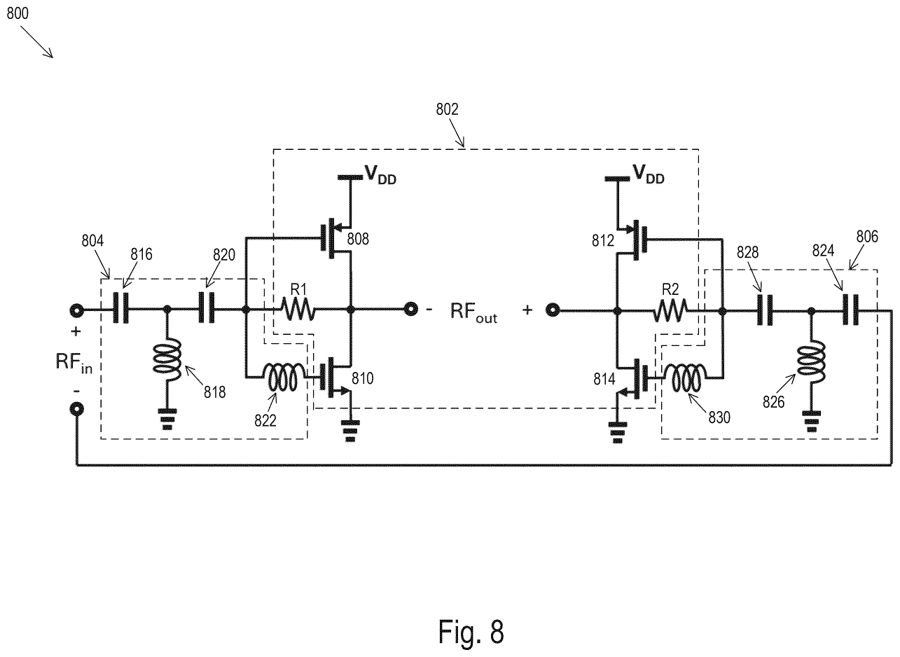

FIGS. 3-12 describe different configurations of the input matching network 202 and the output matching network 206 that help improve the wideband operation of the LNA circuit 200. FIGS. 3-7 disclose using a first example input matching network topology and FIGS. 8-12 disclose using a second example input matching network topology.

FIG. 3 illustrates a differential LNA circuit 300 with an example input matching network that is configured for wideband operation. The differential LNA circuit 300 includes a core amplification stage 302 that is connected to input matching networks 304, 306 corresponding to the two differential inputs of the differential LNA circuit 300.

In some examples, the core amplification stage 302 of the differential LNA circuit 300, which forms the differential amplification path, may be implemented using a complementary cascoding topology similar to the topology described in FIG. 1. In other examples, the core amplification stage 302 of the differential LNA circuit 302 may be implemented using other differential low-noise amplifier topologies.

The input matching network 304 is configured to ensure proper impedance matching between the RF input signal (RFin) and the core amplification stage 302. To achieve wideband operation, the input matching network 304 includes capacitor 316 and capacitor 322 and inductor 318 and inductor 320.

The capacitor 316 act as a DC blocking capacitor, allowing AC signals from the RF input signal RFin to pass through while preventing DC components from interfering with the circuit operation. A DC blocking capacitor prevents unwanted DC components from interfering with the biasing of the core amplification stage 302 of the differential LNA circuit 300, ensuring proper operation and protecting connected RF stages. Without the DC blocking capacitor, capacitor 316, impedance mismatches and low-frequency distortions can degrade signal integrity and affect the differential LNA circuit's 300 bandwidth. For example, the size of the capacitor 316 may be selected to be large enough to allow RF signals to pass through without excessive attenuation. In some examples, the capacitance value may be chosen based on the lowest operating frequency (fc) of the overall RF system, using fc=1/(2πRC), where R is the overall RF system's impedance (typically 50Ω) and C is the capacitor value of capacitor 316.

Inductor 318 is connected to the gate bias voltage (VG) and provides a high impedance at low frequencies, serving as part of the wideband input matching network. The inductor 318 forms a parallel LC circuit with the parasitic capacitance at the gate terminal of the NMOS transistor 310, which helps to extend the operational bandwidth by compensating for capacitive loading and reducing the impact of the Miller effect. Additionally, the inductor 318 provides high impedance at lower frequencies, ensuring proper DC biasing while allowing high-frequency signals to pass with minimal attenuation. The inductance value of inductor 318 may be chosen such that the impedance transformation is optimized and the matching across a broader frequency range is improved, effectively enhancing the wideband performance of the LNA.

Inductor 320 is a series inductor placed between the input node and the gate terminal of the NMOS transistor 310 to helps extend bandwidth by counteracting gate capacitance (Cgs) and to reduce the low-pass filtering effect of the gate capacitance. The use of the inductor 320 improves high-frequency gain and impedance matching.

The values of inductor 318 and inductor 320 are determined based on the desired bandwidth of the differential LNA circuit 300 and by considering the resonance condition and impedance matching requirements. The inductor 318 forms a parallel LC circuit with the gate capacitance (Cgs) of the NMOS transistor 310, which creates a resonant frequency (fres) given by:

$$\\ {f}_{res} = \frac{1}{2 π \sqrt{{LC}_{gs}}}$$

where, L is the inductance of the inductor 318. To extend the bandwidth, the value of inductor 318 is selected such that resonant frequency of inductor 318 aligns with or slightly exceeds the upper limit of the operating frequency range, compensating for parasitic capacitances that would otherwise limit high-frequency performance. For example, a smaller inductor 318 may result in a higher resonant frequency, supporting broader bandwidth but at the cost of increased impedance mismatch. Conversely, a larger inductor 318 lowers the resonance frequency and may restrict the upper-frequency limit of the amplifier.

To achieve wideband matching, inductor 318 may be optimized in conjunction with the inductor 320 and the gate capacitance, ensuring that the overall impedance transformation allows smooth signal transmission across the entire frequency range. The value of inductor 318 can therefore carefully be selected through circuit simulations and S-parameter analysis to ensure optimal trade-offs between bandwidth, gain, and stability in the sub-6 GHZ operating range.

In an example, the input matching network 304 additionally includes capacitor 322 placed between the input node RFin and the gates of the PMOS transistor 308. The capacitor 322 facilitates AC coupling, allowing high-frequency signals to pass while blocking DC components, ensuring proper operation of the cascode structure. Additionally, capacitor 322 contributes to bandwidth extension by interacting with the parasitic capacitances of 308 and controlling gain peaking at high frequencies to counteract gain roll-off. The size of the capacitor 322 may be carefully optimized based on the desired frequency response, ensuring that the size of the capacitor 322 is neither too large, which could cause excessive gain peaking and instability, nor too small, which would limit its bandwidth enhancing effect.

The input matching network 306, on the other side of the core amplification stage 302 of the differential LNA circuit 300 corresponding to the second differential input path, is implemented similar to the input matching network 304. The input matching network 306 consists of capacitor 324, inductor 326, inductor 328 and capacitor 330 that mirror the implementation and role of their counterparts capacitor 316, inductor 318, inductor 320, and capacitor 322 respectively from the input matching network 304. Capacitors 324 and 330 act as DC blocking elements, that together with inductors 326 and 328 are tuned to a particular impedance to match other components within a broader system (typically 50 ohms for RF systems) to maintain broadband operation.

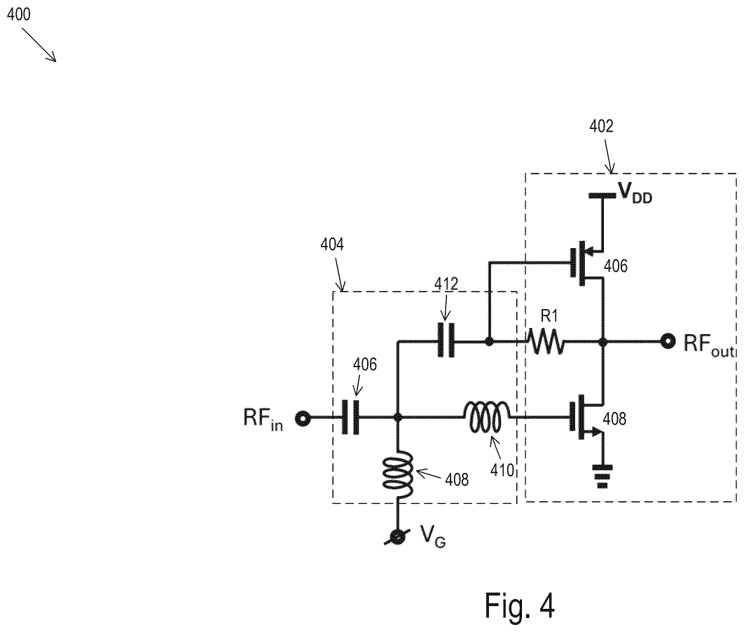

FIG. 4 illustrates a single ended LNA circuit 400 with the example input matching network that is configured for wideband operation. The single ended LNA circuit 400 is configured to include a core amplification stage 402 that is connected to an input matching network 404.

The core amplification stage 402 is a configured for single ended input and output signals. The core amplification stage 402 includes a cascoding topology similar to the structure created by one side of the differential LNA circuit 300 from FIG. 3. The PMOS transistor 406, NMOS transistor 408 and resistor R1 correspond to the PMOS transistor 308, NMOS transistor 310 and resistor R1 from FIG. 3 respectively.

The input matching network 404 is also configured to correspond to the input matching network 304 from FIG. 3 and includes capacitor 410, inductor 412, inductor 414 and capacitor 416 that correspond to capacitor 316, inductor 318, inductor 416 and capacitor 414 respectively. The capacitors 410, 416 and inductors 412, 414 from input matching network 404 are implemented and sized in a manner similar to the components of the input matching network 304 from FIG. 3.

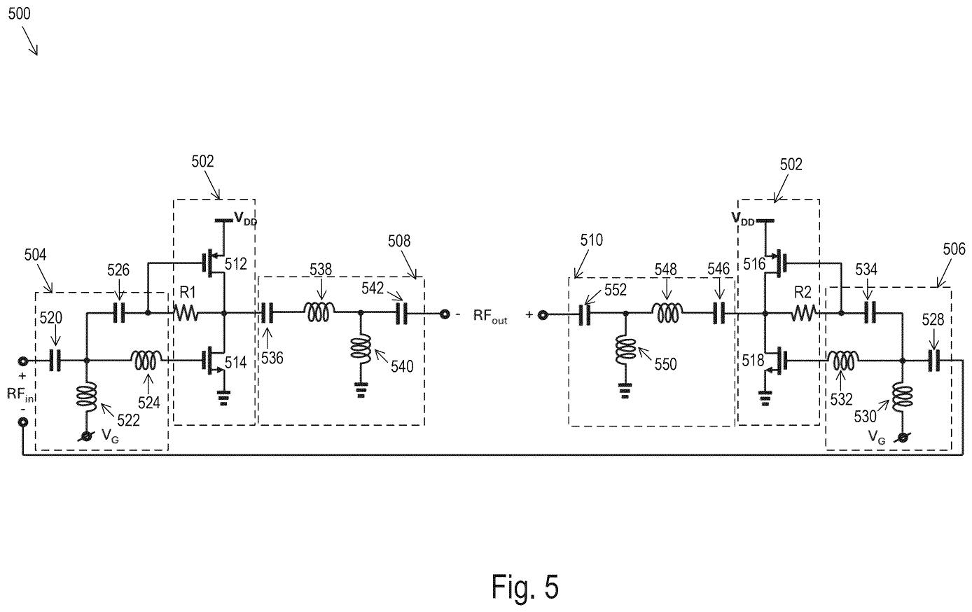

FIG. 5 illustrates a differential LNA circuit 500 with the example input matching network and an example output matching network, both configured for wideband operations. The differential LNA circuit 500 includes a core amplification stage 502 that is connected to input matching networks 504, 506 and to output matching networks 508, 510 corresponding to the two differential inputs of the differential LNA circuit 500.

The core amplification stage 502 in the differential LNA circuit 500 is split between the two sections, each corresponding to the two sections of the differential LNA circuit 500. Together, the core amplification section 502 may be implemented using a complementary cascoding topology, including PMOS transistor 512 and NMOS transistor 514 in one section and PMOS transistor 516 and NMOS transistor 518 in the other section, similar to the topology described in FIG. 1. In other examples, the core amplification stage 502 of the differential LNA circuit 502 may be implemented using other differential low-noise amplifier topologies.

Similar to the input matching networks 304 and 306 from FIG. 3, the input matching networks 504 and 506 are configured to ensure proper impedance matching between the RF input signal (RFin) and the core amplification stage 502. To achieve wideband operation, the input matching network 504 includes capacitor 520, capacitor 526, inductor 522 and inductor 524 and the input matching network 506 includes capacitor 528, capacitor 534, inductor 530 and inductor 532. The input matching networks 504 and 506 and the corresponding components, capacitor 520, capacitor 526, inductor 522 and inductor 524 are implemented and sized in a manner similar to the input matching networks 304 and 306 and the corresponding components capacitor 528, capacitor 534, inductor 530 and inductor 532 respectively.

In addition to the input matching networks 504 and 506, the differential LNA circuit 500 also includes output matching networks 508 and 510 connected to the core amplification stage 502. For example, the drain terminal of the PMOS transistor 512 and the drain terminal of the NMOS transistor 514 are connected to the output matching network 508 and the drain terminal of the PMOS transistor 516 and the drain terminal of the NMOS transistor 518 are connected to the output matching network 510.

The output matching networks 508, 510 are tuned to achieve wideband operation by matching the output impedance of the differential LNA circuit 500 to 50 ohms. Generally, in RF systems, the standard impedance for most transmission lines, antennas, and RF front-end components, including mixers, is 50 ohms. Since the present differential LNA circuit 500 is designed to be used in a RF application where the differential LNA circuit 500 is likely connected to an I/Q mixer module 112, proper impedance matching between the output of the differential LNA circuit 500 and the I/Q mixer module 112 ensures maximum power transfer while minimizing signal reflections, which can otherwise result in standing waves, increased noise, and signal distortion. If the output impedance of the LNA does not match 50 ohms, it can lead to mismatched loading conditions, reducing the overall system efficiency and potentially degrading the signal-to-noise ratio (SNR). By designing the output matching network to precisely match this impedance, the LNA can deliver its amplified signal with minimal losses, ensuring that the mixer receives a clean and stable RF input, which may be needed for accurate signal down-conversion and demodulation in modern RF communication systems.

The output matching networks 508 and 510 are composed of two capacitors and two inductors. For example, in the output matching network 508, the drain terminals of PMOS transistor 512 and NMOS transistor 514 are connected to a first terminal of the capacitor 536. The second terminal of the capacitor 536 is connected in series to the first terminal of the inductor 538. The second terminal of the inductor 538 is connected to the inductor 540 in a shunt configuration and the first terminal of the capacitor 542. The second terminal of the capacitor 542 is connected to the one of the differential output terminals, RFout. In some examples where the differential LNA circuit 500 is part of an overall RF system, the output terminal RFout is connected to the next component, which may include an I/Q mixer module 112 as shown in FIG. 2.

Similar to the output matching network 508, the output matching network 510 that is connected to the other section of the core amplification stage 502 is also composed of two capacitors and two inductors. For example, in the output matching network 510, the drain terminals of PMOS transistor 516 and NMOS transistor 518 are connected to a first terminal of the capacitor 546. The second terminal of the capacitor 546 is connected in series to the first terminal of the inductor 548. The second terminal of the inductor 548 is connected to the inductor 550 in a shunt configuration and the first terminal of the capacitor 552. The second terminal of the capacitor 552 is connected to the other differential output terminal, RFout. In some examples where the differential LNA circuit 500 is part of an overall RF system, the output terminal RFout is connected to the next component, which may include an I/Q mixer module 112 as shown in FIG. 2.

The capacitors 536 and 542 primarily function as DC blocking elements, preventing DC bias from interfering with subsequent stages while allowing high-frequency signals to pass through. Beyond DC blocking, the capacitors 536 and 542 contribute to impedance matching by interacting with the inductors 538 and 540 and the parasitic capacitances of active devices, ensuring minimal signal loss and maintaining a flat gain response over a broad bandwidth. The values of the capacitors 536 and 542 are selected to balance high-frequency roll-off and resonance effects, ensuring that the differential LNA circuit 500 operates efficiently across its intended frequency range.

The inductors 538 and 540 play a crucial role in broadband impedance transformation and high-frequency stability. The inductors 538 and 540 help counteract parasitic capacitances at the output of the differential LNA circuit 500, which could otherwise degrade performance by introducing undesired signal attenuation or peaking. By tuning the values of the inductors 538 and 540, the differential LNA circuit 500 may achieve wideband matching, reducing standing wave reflections and ensuring maximum power transfer to the I/Q mixer module 112. Additionally, the inductors 538 and 540 aid in shaping the overall frequency response, contributing to gain flatness and phase stability.

The output matching network 510, on the other side of the core amplification stage 502 of the differential LNA circuit 500, functions similarly to the output matching network 508 but corresponds to the second differential output path. The output matching network 510 consists of capacitor 546, inductor 548, inductor 550 and capacitor 552 that mirror the roles of their counterparts capacitor 536, inductor 538, inductor 540 and capacitor 542 respectively in the output matching network 508. Capacitors 546 and 552 act as DC blocking elements and together with inductors 548 and 550 are tuned to match the differential LNA circuit's 500 output impedance to the impedance of the next component of the overall RF system.

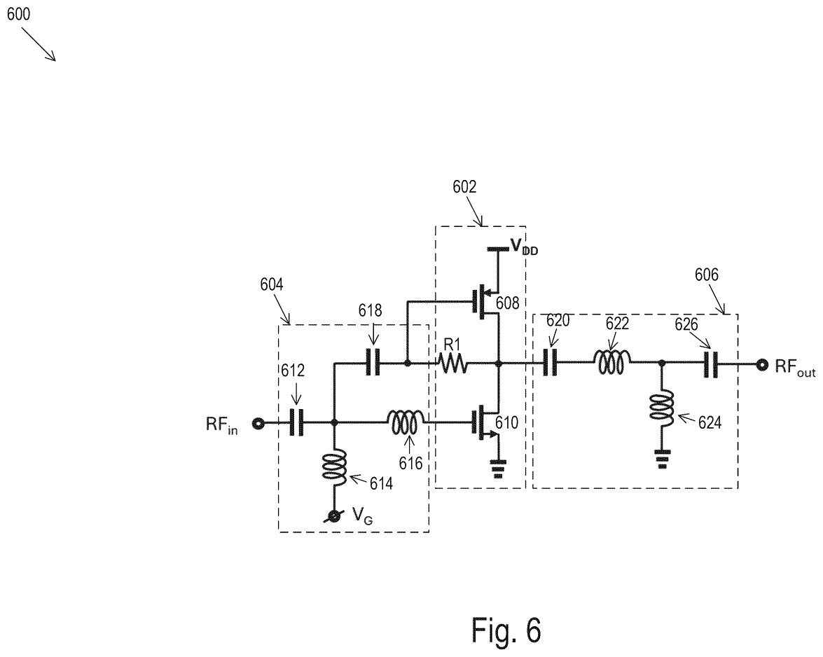

FIG. 6 illustrates a single ended LNA circuit 600 with the example input matching network and the example output matching network both configured for wideband operations. The single ended LNA circuit 600 is configured to include a core amplification stage 602 that is connected to an input matching network 604 and an output matching network 606.

The core amplification stage 602 is a configured for single ended input and output signals. The core amplification stage 602 includes a cascoding topology similar to the structure created by one side of the differential LNA circuit 500 from FIG. 5 that includes the PMOS transistor 608, the NMOS transistor 610, and resistor R1.

The input matching network 604 is configured to correspond to the input matching network 504 from FIG. 5 and includes capacitor 612, inductor 614, inductor 616 and capacitor 618 that correspond to capacitor 520, inductor 522, inductor 524 and capacitor 526 respectively from FIG. 5. The capacitors 612, 618 and inductors 614, 614 from input matching network 604 are implemented and sized in a manner similar to described above in relation to the input matching network 504 from FIG. 5.

The output matching network 606 is configured to correspond to the output matching network 508 from FIG. 5 and includes capacitor 620, inductor 622, inductor 624 and capacitor 626 that correspond to capacitor 536, inductor 538, inductor 540 and capacitor 542 respectively from FIG. 5. The capacitors 620, 626, and inductors 622, 624 from output matching network 604 are implemented and sized in a manner similar to described above in relation to the output matching network 508 from FIG. 5.

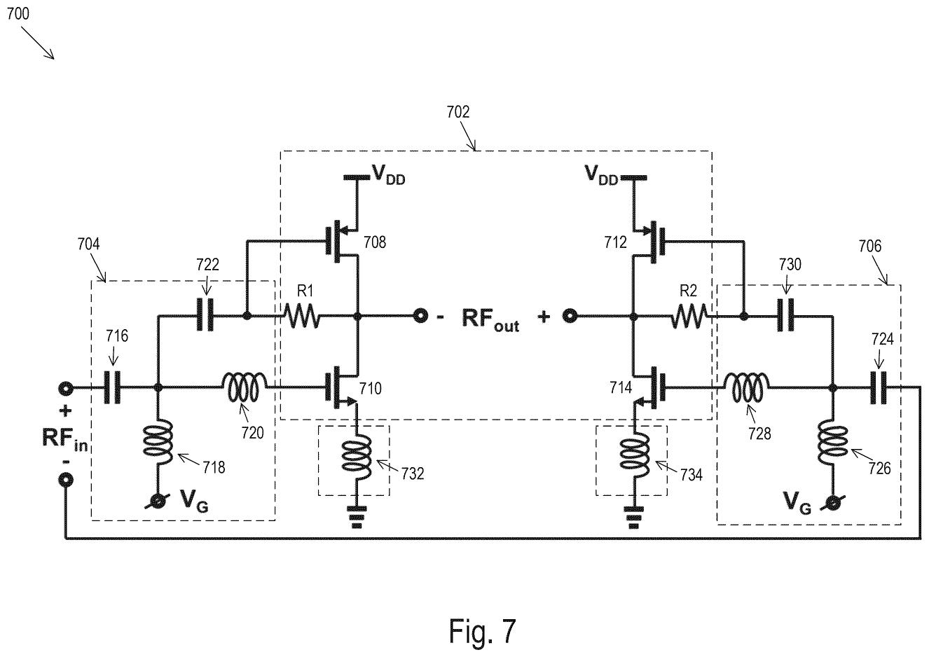

FIG. 7 illustrates a differential LNA circuit 700 with the example input matching network that is configured for source degeneration and wideband operations. The differential LNA circuit 700 includes a core amplification stage 702 and input matching networks 704, 706 that are implemented with a similar topology as the differential LNA circuit 300 from FIG. 3.

The core amplification stage 702 includes a complementary cascoding topology, with each side of the differential circuit including PMOS transistors 708, 712 and NMOS transistors 710, 714 that are implemented in a manner similar to the PMOS transistors 308, 312 and NMOS transistors 310, 314 from FIG. 3. Further, the input matching network 704 includes two capacitors 716, 722 and two inductors 718, 720 that are implemented in a manner similar to the two capacitors 316, 322 and two inductors 318, 322 of input matching network 304 from FIG. 3 and the input matching network 306 includes two capacitors 724, 730 and two inductors 726, 728 that are implemented in a manner similar to the two capacitors 324, 330 and two inductors 326, 328 of input matching network 306 from FIG. 3.

The differential LNA circuit 700, differs from the differential LNA circuit 300 from FIG. 3 at least because of the incorporation of the source degeneration inductors 732, 734. The source degeneration inductor 732 is connected in series to the source terminal of the NMOS transistor 710 and the source degeneration inductor 734 is connected in series to the source terminal of the NMOS transistor 714. Although FIG. 7 uses inductors to achieve source degeneration, in some examples, resistors can be used to achieve source degeneration as well.

Connecting the source degeneration inductors 732, 734 in series with the source terminal of the NMOS transistors 710 and 714 helps improve the input impedance matching of the differential LNA circuit 700. The source degeneration inductors 732, 734 introduces a controlled impedance to the source terminal of the NMOS transistors 710, 714, which helps achieve wideband impedance matching by mitigating parasitic capacitances and preventing excessive variations in the input impedance over frequency.

Additionally, source degeneration inductors 732 and 734 help in reducing the impact of the Miller effect. Without source degeneration, the gate-drain capacitance (Cgd) of the transistor would be amplified due to the feedback loop, limiting the high-frequency performance of the amplifier. By introducing source degeneration, the effective transconductance (gm) is reduced, leading to improved linearity and gain stability across a wide frequency range.

Another advantage of using source degeneration inductors 732, 734 is their contribution to gain peaking and bandwidth extension. The resonance formed between the source degeneration inductors 732, 734 and the parasitic capacitances of the NMOS transistors 710, 714 helps in enhancing gain at higher frequencies, allowing the LNA to operate efficiently over a broad bandwidth. This is particularly useful in sub-6 GHz RF applications, where wideband operation is necessary to support high-data-rate communications.

In some examples, the source degeneration inductors 732, 734 are sized based on the desired impedance matching, gain stability, and bandwidth extension. The value of the source degeneration inductors 732, 734 are calculated using input impedance formulas and resonant frequency considerations, then fine-tuned through circuit simulations to optimize the performance of the LNA in high-frequency RF applications.

Although FIG. 7 illustrates a differential LNA circuit 700 with only input matching networks achieving source degeneration using inductors 732, 734, a similar source degeneration technique may be adapted and applied to single ended LNA circuits 400 and 600 from FIGS. 4 and 6 respectively and to differential LNA circuit 500 from FIG. 5.

FIG. 8 illustrates a differential LNA circuit 800 with another example input matching network that is also configured for wideband operation. The differential LNA circuit 800 includes a core amplification stage 802 that is connected to the input networks 804 and 806 corresponding to the two differential inputs of the differential LNA circuit 800.

In some examples, the core amplification stage 802 of the differential LNA circuit 800, which forms the differential amplification path, may be implemented using a complementary cascoding topology similar to the topology described in FIG. 1. In other examples, the core amplification stage 802 of the differential LNA circuit 802 may be implemented using other differential low-noise amplifier topologies.

The differential LNA circuit 800 utilizes a C-L-C Y network topology for the input matching networks 804 and 806 for wideband operations, which differs from the topology used for the input matching network in FIGS. 3-7. The input matching networks 804 and 806 are configured to ensure proper matching between the RF input signal (RFin) and the core amplification stage 302.

Capacitor 816 may serve as a DC-blocking capacitor, preventing any unwanted DC bias from interfering with the operations of the differential LNA circuit 800 while allowing the high-frequency RF input signal to pass. In addition to DC isolation, capacitor 816 also contributes to impedance tuning by forming a high-pass filter in conjunction with the inductor 818. In some examples, carefully selecting the capacitance value of capacitor 816 helps control the low-frequency cutoff point, ensuring that the amplifier effectively operates over a broad frequency range.

Inductor 818 is part of the shunt inductive element in the input matching network. For example, inductor 818 introduces a reactive component that helps counteract the capacitive loading effects of the NMOS transistor's 810 gate and parasitic capacitances in the signal path. By providing a high impedance path at lower frequencies while resonating with the input capacitance at higher frequencies, inductor 818 helps maintain a broadband impedance match, allowing the differential LNA circuit 800 to work efficiently over a wide range of operating frequencies.

Capacitor 820 is another DC-blocking element, positioned in series to ensure that the RF signal is coupled properly into the differential LNA circuit 800 while preventing DC bias from the active devices from reaching the previous stage. Beyond DC isolation, 820 also interacts with inductor 818 to form a resonant circuit, aiding in the impedance transformation and flattening the gain response across the operational bandwidth. This capacitive element is particularly useful in high-frequency RF applications, where controlling impedance variations may help minimize signal reflections and insertion losses.

Inductor 822 serves as an additional impedance tuning component, contributing to the series-shunt matching network. The placement of the inductor 822, connected between the gate terminal of the NMOS transistor 810 and the rest of the components of the input matching network 804, allows it to work in conjunction with inductor 818 to create a multi-resonant structure, which extends the bandwidth of the LNA. By adjusting the value of 822, the impedance transformation can be fine-tuned, ensuring that the differential LNA circuit's 800 input impedance remains close to the output impedance of a component connected to the input of the differential LNA circuit 800, typically 50 ohms in an RF system, across a broad frequency range. This is particularly important for wideband RF systems, where multiple frequency bands must be efficiently amplified without significant loss.

The input matching network 806, on the other side of the core amplification stage 802 of the differential LNA circuit 800 corresponding to the second differential input path, is implemented similar to the input matching network 804. The input matching network 806 consists of capacitor 824, inductor 826, capacitor 828 and inductor 830 that mirror the implementation and role of their counterparts capacitor 816, inductor 818, capacitor 820 and inductor 822 respectively from the input matching network 804. Capacitors 824 and 828 act as DC blocking elements, that together with inductors 826 and 830 are tuned to a particular impedance to match other components within a broader system (typically 50 ohms for RF systems) to maintain broadband operation.

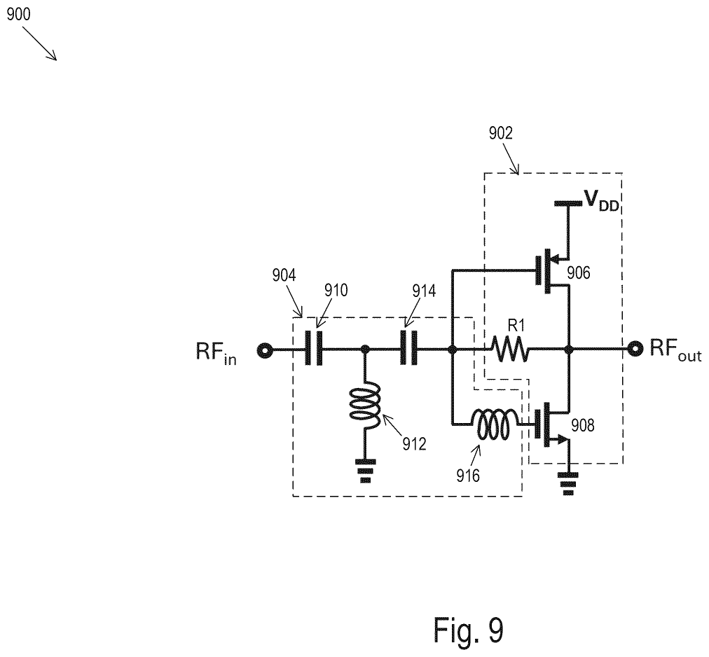

FIG. 9 illustrates a single ended LNA circuit 900 with the example input matching network that is configured for wideband operation. The single ended LNA circuit 900 is configured to include a core amplification stage 902 that is connected to an input matching network 904.

The core amplification stage 902 is a configured for single ended input and output signals. The core amplification stage 902 includes a cascoding topology similar to the structure created by one side of the differential LNA circuit 800 from FIG. 8. The PMOS transistor 906, NMOS transistor 908 and resistor R1 correspond to the PMOS transistor 808, NMOS transistor 810 and resistor R1 from FIG. 8 respectively.

The input matching network 904 is also configured to correspond to the input matching network 804 from FIG. 8 and includes capacitor 910, inductor 912, capacitor 914, and inductor 916 that correspond to capacitor 816, inductor 818, capacitor 820, and inductor 822 respectively. The capacitors 910, 914 and inductors 912, 916 from input matching network 904 are implemented and sized in a manner similar to the components of the input matching network 804 from FIG. 8.

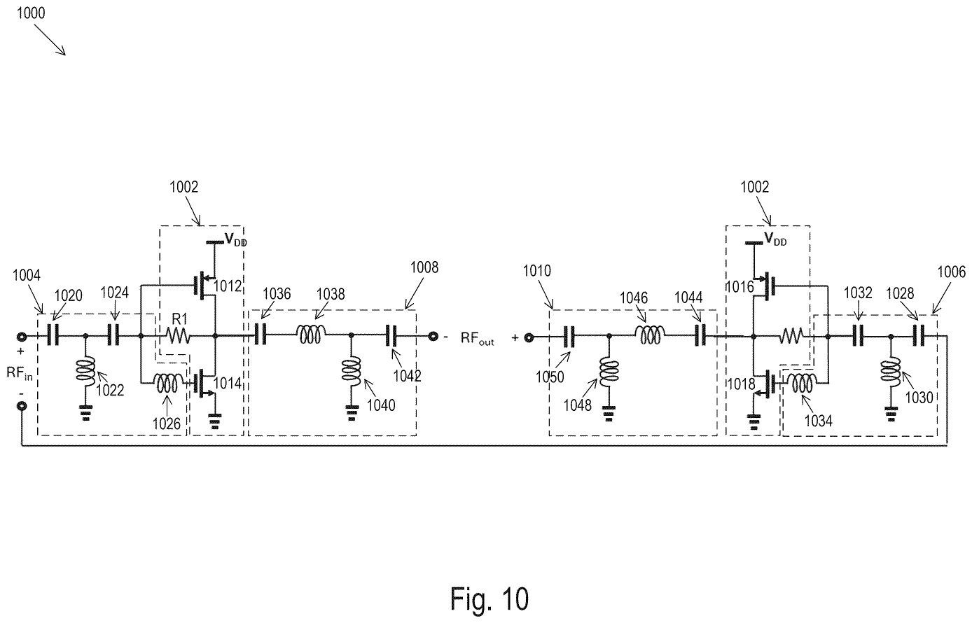

FIG. 10 illustrates a differential LNA circuit 1000 with the example input matching network and an example output matching network, both configured for wideband operations. The differential LNA circuit 1000 includes a core amplification stage 1002 that is connected to input matching networks 1004, 1006 and to output matching networks 1008, 1010 corresponding to the two differential inputs of the differential LNA circuit 1000.

The core amplification stage 1002 in the differential LNA circuit 1000 is split between the two sections, each corresponding to the two sections of the differential LNA circuit 1000. Together, the core amplification section 1002 may be implemented using a complementary cascoding topology, including PMOS transistor 1012 and NMOS transistor 1014 in one section and PMOS transistor 1016 and NMOS transistor 1018 in the other section, similar to the topology described in FIG. 1. In other examples, the core amplification stage 1002 of the differential LNA circuit 1002 may be implemented using other differential low-noise amplifier topologies.

Similar to the input matching networks 804 and 806 from FIG. 8, the input matching networks 1004 and 1006 are configured to ensure proper impedance matching between the RF input signal (RFin) and the core amplification stage 1002. To achieve wideband operation, the input matching network 1004 includes capacitor 1020, capacitor 1024, inductor 1022 and inductor 1026 and the input matching network 1006 includes capacitor 1028, capacitor 1032, inductor 1030 and inductor 1034. The input matching network 1004 and the corresponding components, capacitor 1020, capacitor 1024, inductor 1022 and inductor 1026 are implemented and sized in a manner similar to the input matching network 804 and the corresponding components capacitor 816, capacitor 820, inductor 818 and inductor 822 respectively from FIG. 8. The input matching network 1006 and the corresponding components, capacitor 1028, capacitor 1032, inductor 1030 and inductor 1034 are implemented and sized in a manner similar to the input matching network 806 and the corresponding components capacitor 824, capacitor 828, inductor 826 and inductor 830 respectively from FIG. 8.

In addition to the input matching networks 1004 and 1006, the differential LNA circuit 1000 also includes output matching networks 1008 and 1010 connected to the core amplification stage 1002. For example, the drain terminal of the PMOS transistor 1012 and the drain terminal of the NMOS transistor 1014 are connected to the output matching network 1008 and the drain terminal of the PMOS transistor 1016 and the drain terminal of the NMOS transistor 1018 are connected to the output matching network 1010.

The output matching networks 1008, 1010 are tuned to achieve wideband operation by matching the output impedance of the differential LNA circuit 1000 to the input impedance of the next component connected to the differential LNA circuit 1000. If the differential LNA circuit 1000 is part of an overall RF system, the output impedance of the differential LNA circuit 1000 is typically matched to 50 ohms

The output matching networks 1008 and 1010 are composed of two capacitors and two inductors according to a similar topology as the output matching networks 508 and 510 from FIG. 5. For example, in the output matching network 1008, the drain terminals of PMOS transistor 1012 and NMOS transistor 1014 are connected to a first terminal of the capacitor 1036. The second terminal of the capacitor 1036 is connected in series to the first terminal of the inductor 1038. The second terminal of the inductor 1038 is connected to the inductor 1040 in a shunt configuration and the first terminal of the capacitor 1042. The second terminal of the capacitor 1042 is connected to the one of the differential output terminals, RFout. In some examples where the differential LNA circuit 1000 is part of an overall RF system, the output terminal RFout is connected to the next component, which may include an I/Q mixer module 112 as shown in FIG. 2.

Similar to the output matching network 1008, the output matching network 1010 that is connected to the other section of the core amplification stage 1002 is also composed of two capacitors and two inductors. For example, in the output matching network 1010, the drain terminals of PMOS transistor 1016 and NMOS transistor 1018 are connected to a first terminal of the capacitor 1044. The second terminal of the capacitor 1044 is connected in series to the first terminal of the inductor 1046. The second terminal of the inductor 1046 is connected to the inductor 1048 in a shunt configuration and the first terminal of the capacitor 1050. The second terminal of the capacitor 1050 is connected to the other differential output terminal, RFout. In some examples where the differential LNA circuit 500 is part of an overall RF system, the output terminal RFout is connected to the next component, which may include an I/Q mixer module 112 as shown in FIG. 2.

The components of the output matching networks 1008 and 1010 are implemented and sized similar to the components of the output matching networks 508 and 510 respectively and perform functions similar to the respective components from the output matching networks 508 and 510.

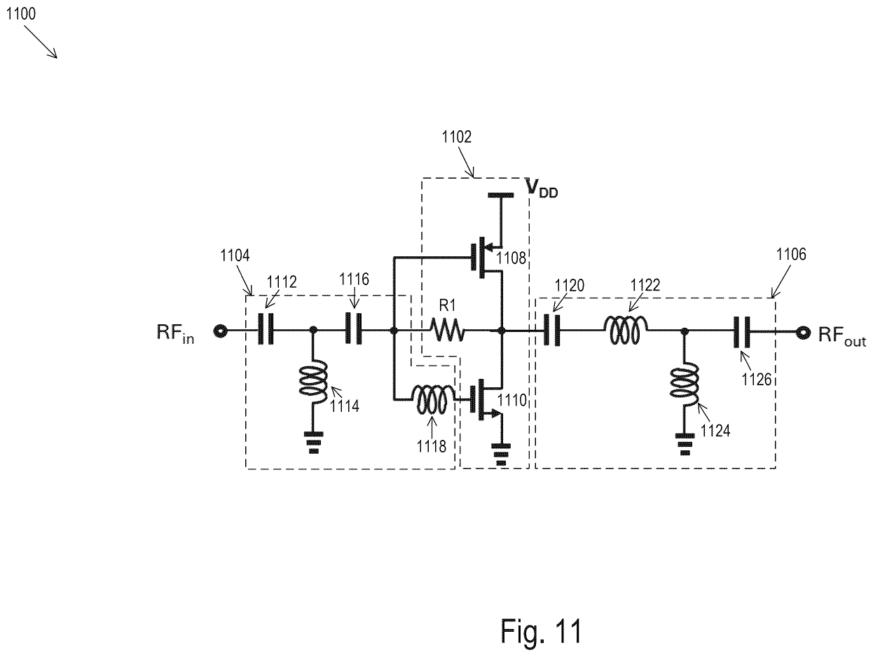

FIG. 11 illustrates a single ended LNA circuit 1100 with the example input matching network and the example output matching network both configured for wideband operations. The single ended LNA circuit 1100 is configured to include a core amplification stage 1102 that is connected to an input matching network 1104 and an output matching network 1106.

The core amplification stage 1102 is a configured for single ended input and output signals. The core amplification stage 1102 includes a cascoding topology similar to the structure created by one side of the differential LNA circuit 1000 from FIG. 10 and includes the PMOS transistor 1108, the NMOS transistor 1110, and resistor R1.

The input matching network 1104 is configured to correspond to the input matching network 1004 from FIG. 10 and includes capacitor 1112, inductor 1114, capacitor 1116 and capacitor 1118 that correspond to capacitor 1020, inductor 1022, capacitor 1024 and inductor 1026 respectively from FIG. 10. The capacitors 1112, 1116 and inductors 1114, 1118 from input matching network 1104 are implemented and sized in a manner similar to described above in relation to the input matching network 1004 from FIG. 10.

The output matching network 1106 is configured to correspond to the output matching network 1008 from FIG. 10 and includes capacitor 1120, inductor 1122, inductor 1124 and capacitor 1126 that correspond to capacitor 1036, inductor 1038, inductor 1040 and capacitor 1042 respectively from FIG. 10. The capacitors 1120, 1126, and inductors 1122, 1124 from output matching network 1104 are implemented and sized in a manner similar to described above in relation to the output matching network 1008 from FIG. 10.

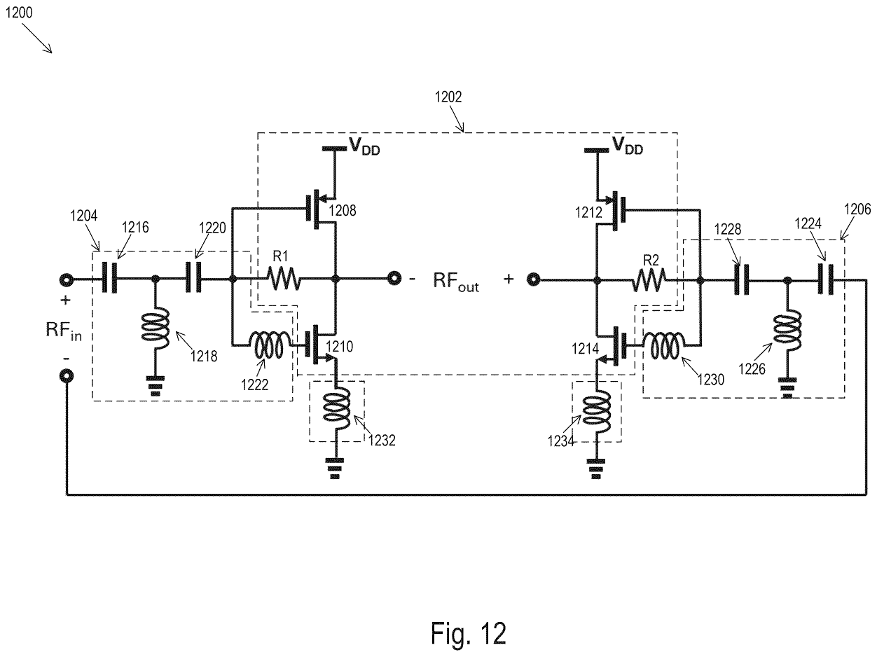

FIG. 12 illustrates a differential LNA circuit 1200 with the example input matching network that is configured for source degeneration and wideband operations. The differential LNA circuit 1200 includes a core amplification stage 1102 and input matching networks 1106, 1108 that are implemented with a similar topology as the differential LNA circuit 800 from FIG. 8.

The core amplification stage 1102 includes a complementary cascoding topology, with each side of the differential circuit including PMOS transistors 1110, 1112 and NMOS transistors 1112, 1214 that are implemented in a manner similar to the PMOS transistors 808, 812 and NMOS transistors 810, 814 from FIG. 8. Further, the input matching network 1106 includes two capacitors 1216, 1220 and two inductors 1218, 1222 that are implemented in a manner similar to the two capacitors 816, 820 and two inductors 818, 820 of input matching network 804 from FIG. 8 and the input matching network 1108 includes two capacitors 1224, 1228 and two inductors 1226, 1230 that are implemented in a manner similar to the two capacitors 824, 828 and two inductors 826, 830 of input matching network 806 from FIG. 8.

The differential LNA circuit 1200, differs from the differential LNA circuit 800 from FIG. 8 at least because of the incorporation of the source degeneration inductors 1232, 1234. The source degeneration inductor 1232 is connected in series to the source terminal of the NMOS transistor 1112 and the source degeneration inductor 1234 is connected in series to the source terminal of the NMOS transistor 1214. Although FIG. 12 uses inductors to achieve source degeneration, in some examples, resistors can be used to achieve source degeneration as well.

Connecting the source degeneration inductors 1232, 1234 in series with the source terminal of the NMOS transistors 1112 and 1214 helps improve the input impedance matching of the differential LNA circuit 1200. The source degeneration inductors 1232, 1234 introduces a controlled impedance to the source terminal of the NMOS transistors 1112, 1214, which helps achieve wideband impedance matching by mitigating parasitic capacitances and preventing excessive variations in the input impedance over frequency.

Additionally, source degeneration inductors 1232 and 1234 help in reducing the impact of the Miller effect. Without source degeneration, the gate-drain capacitance (Cgd) of the transistor would be amplified due to the feedback loop, limiting the high-frequency performance of the amplifier. By introducing source degeneration, the effective transconductance (gm) is reduced, leading to improved linearity and gain stability across a wide frequency range.

Another advantage of using source degeneration inductors 1232, 1234 is their contribution to gain peaking and bandwidth extension. The resonance formed between the source degeneration inductors 1232, 1234 and the parasitic capacitances of the NMOS transistors 1112, 1214 helps in enhancing gain at higher frequencies, allowing the LNA to operate efficiently over a broad bandwidth. This is particularly useful in sub-6 GHz RF applications, where wideband operation is necessary to support high-data-rate communications.

In some examples, the source degeneration inductors 1232, 1234 are sized based on the desired impedance matching, gain stability, and bandwidth extension. The value of the source degeneration inductors 1232, 1234 are calculated using input impedance formulas and resonant frequency considerations, then fine-tuned through circuit simulations to optimize the performance of the LNA in high-frequency RF applications.

Although FIG. 12 illustrates a differential LNA circuit 1200 with only input matching networks achieving source degeneration using inductors 1232, 1234, a similar source degeneration technique may be adapted and applied to single ended LNA circuits 900 and 1100 from FIGS. 9 and 11 respectively and to differential LNA circuit 1000 from FIG. 10.

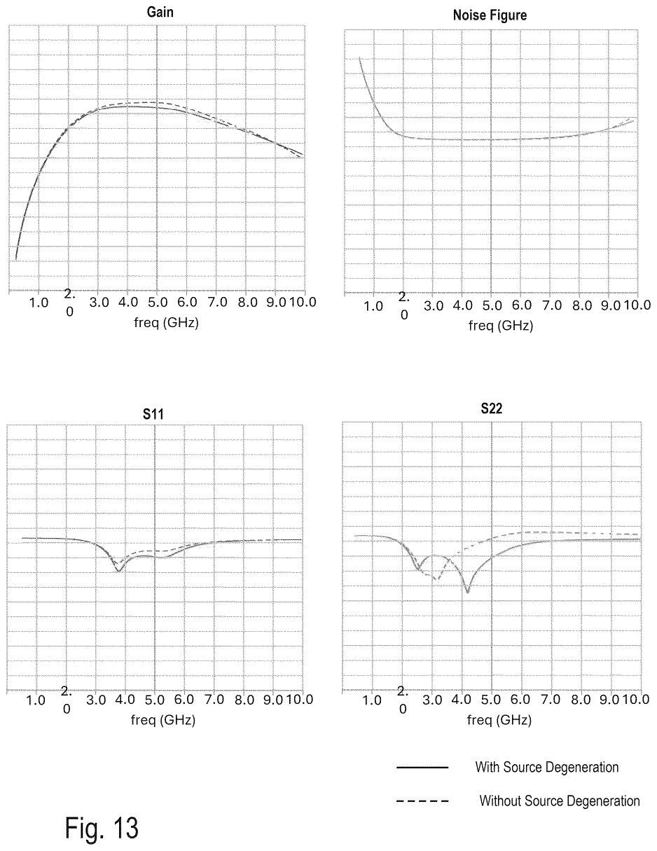

FIG. 13 illustrates the output parameters of the differential LNA circuits from FIGS. 3 and 7. FIG. 13 illustrates the simulation results showing the difference in performance across various output parameters with and without source degeneration as described by the differential LNA circuits 300 and 700 from FIGS. 3 and 7 respectively. FIG. 13 includes 4 separate simulated graphs illustrating the gain performance of the differential LNA circuits 300 and 700, the noise figure performance of the differential LNA circuits 300 and 700, the input reflection coefficient (S11) performance of the differential LNA circuits 300 and 700 and the output reflection coefficient (S22) performance of the differential LNA circuits 300 and 700. The graphs illustrate the output performance of the differential LNA circuits 300 and 700 across a frequency range from 1 to 10 GHz. As illustrated by the graphs, all output performance parameters are improved with the source degeneration implemented in FIG. 7.

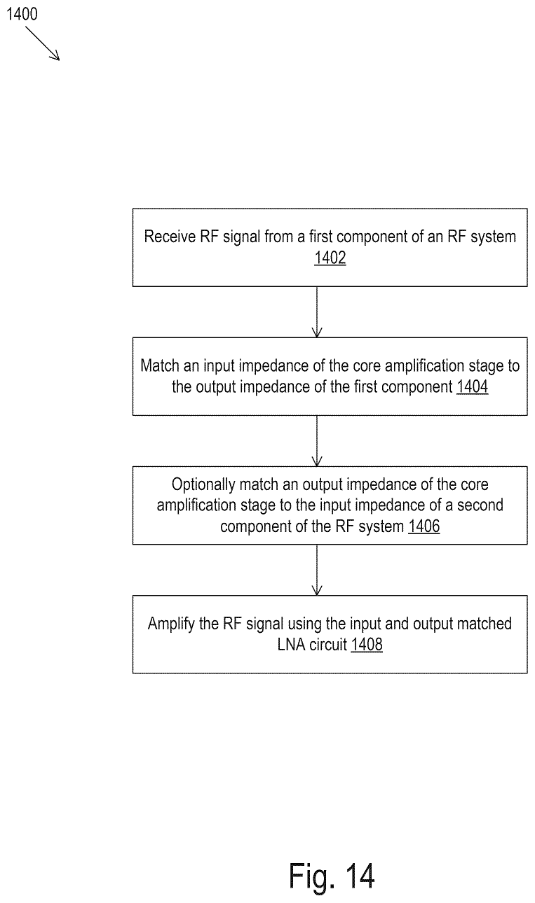

FIG. 14 illustrates an example method 1400 of amplifying an RF signal using the LNA circuit from any of FIGS. 3-12. In some examples, method 1400 may include operations 1402-1408. In other examples, method 1400 may include more or less number of operations.

In example operation 1402, an LNA circuit, such as LNA circuit 104, which is part of an RF system 100 from FIG. 1, may receive an RF signal from a first component. In some examples, the first component of the RF system may include an antenna and the LNA circuit may receive the RF signal from the antenna. In other examples, the first component of the RF system may include a different component.

The LNA circuit receiving the RF signal in operation 1402 may be implemented using any of the LNA circuit topologies described in FIGS. 3-12, including single ended or differential LNA circuits. The LNA circuit may include an input port and an output port and may include a core amplification stage, an input matching network and, optionally, an output matching network.

In example operation 1404, an input matching network may be used to match an input impedance of the core amplification stage of the LNA circuit to the output impedance of the first component. In an example where the LNA circuit is part the RF system 100, the input matching network may match the input impedance the of the LNA circuit to the output impedance of the antenna. The input matching network may be coupled between the input port and the core amplification stage of the LNA circuit. The input matching network may be implemented using a combination of capacitors and inductors, including using the input matching network topology described in FIGS. 3-7 or using the input matching network topology described in FIGS. 8-12.

In example operation 1406, an output matching network may be optionally used to match an output impedance of the core amplification stage of the LNA circuit to the input impedance of a second component within the RF system. In an example where the LNA circuit is part the RF system 100, the output matching network may match the output impedance the of the LNA circuit to the input impedance of the mixer. The output matching network may be coupled between the output port and the core amplification stage of the LNA circuit. The output matching network may be implemented using a combination of capacitors and inductors, including using the output matching network topology described in FIGS. 5-7 or using the input matching network topology described in FIGS. 10-12.

In example operation 1408, the LNA circuit with an input matching network and optionally including an output matching network may be used to amplify the RF input signal to create a low noise RF output signal with stable gain over a wide bandwidth. For example, an LNA circuit with an input matching network and output matching network topology as described in FIGS. 3-12 may be used to amplify an input RF signal. The input matching network and the output matching network help optimize performance, particularly in RF and high frequency applications, by ensuring efficient power transfer, minimal signal reflections and better noise performance over an extended bandwidth.

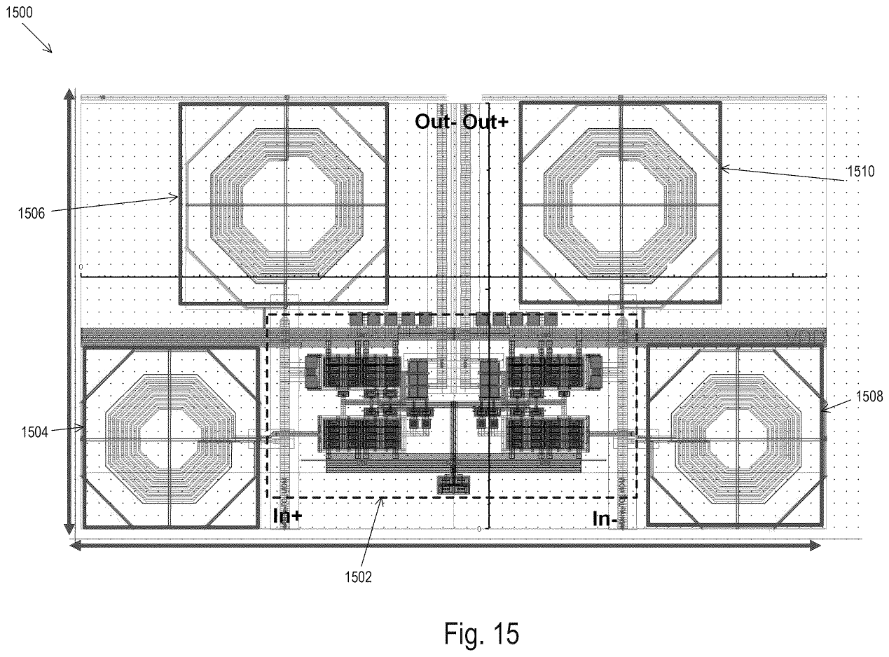

FIG. 15 illustrates an example layout view 1500 of the differential LNA circuit with an example input matching network that is configured for wideband operation from FIG. 3. The layout view 1500 is configured to integrate the input matching network components—including inductors and capacitors—entirely on-chip, eliminating the need for discrete external components to achieve impedance matching and bandwidth extension.

Although FIG. 15 illustrates a layout view corresponding to the schematic view of FIG. 3, similar layout techniques may be used to implement the input matching network and related components for any of the LNA circuit embodiments described in FIGS. 1-14. For example, differential or single-ended LNAs with alternative matching network topologies, output matching networks, or source degeneration structures may also benefit from the same on-chip integration strategy, metal layer utilization, and shielding techniques illustrated in FIG. 15.

Integrating the entire matching network on-chip, particularly with spiral inductors, may be advantageous in high-frequency applications due to the avoidance of parasitic inductance and capacitance commonly introduced by off-chip routing and packaging. These parasitics may limit the achievable bandwidth and degrade gain or noise figure in RF circuits. By embedding both the inductors and capacitors directly within the top metal layers of the integrated circuit, the matching network may achieve higher signal integrity, reduced package loss, and improved wideband performance in compact form factors. However, implementing inductors on-chip introduces design challenges, including managing low Q-factors, minimizing substrate coupling, and preserving layout density.

The layout view 1500 is organized such that the core amplification stage 302 is centrally located and is identified as region 1502. The core amplification stage 302 may include portions of the input matching networks 304 and 306 from FIG. 3 and may contain the layout for active LNA devices, such as the transistors and bias resistors, and also the capacitors 316, 322, 324, and 330 from the matching networks 304 and 306. The surrounding components, identified as 1504, 1506, 1508, and 1510, represent the layout views for the spiral inductors.

Specifically, component 1504 corresponds to inductor 318 of the matching network 304 from FIG. 3, component 1506 corresponds to inductor 320 of the matching network 304, component 1508 corresponds to inductor 326 of the matching network 306, and component 1510 corresponds to inductor 328 of the matching network 306. These inductors may be symmetrically distributed around the core amplification stage 1502 to maintain balanced signal paths and minimize interconnect lengths.

In one example, each of the inductor layout regions 1504, 1506, 1508, and 1510 may occupy an area ranging from approximately 70×70 μm² to 85×85 μm². The inductors may be implemented using the top-most metal layer(s) of the process stack, which may include ultra-thick copper layers such as M9 or M10, depending on the specific process technology. The total metal thickness for the inductor layer may be approximately 3 μm. Metal layers below the top layer, such as M2 through M5, may be used to route signal interconnects and implement the active circuit elements and capacitor structures of the LNA.

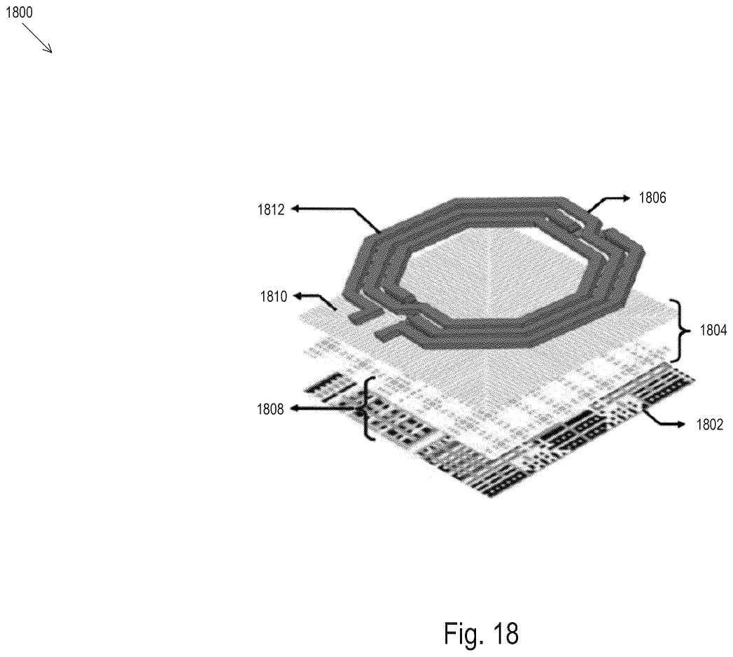

The layout view 1500 may also support alternative integration approaches where the inductors are implemented using the top metal layers and the remaining circuit elements—including MOS transistors and capacitors—are placed underneath. As illustrated in greater detail in FIG. 18, the active and passive devices may be located in the lower or middle metal layers, with the inductors laid out above them. In such configurations, it may be desirable to include patterned ground shielding (PGS) beneath the inductors to reduce electromagnetic coupling and substrate noise injection from the underlying circuitry.

In one implementation, the inductors may also be realized using dual ultra-thick metal, or “double Mu,” technology, which involves stacking two ultra-thick metal layers (e.g., M9 and M10) at the top of the metal stack. This approach increases the vertical distance between the inductive traces and the lossy substrate, thereby reducing substrate coupling and improving the quality factor (Q-factor) of the inductors. For example, a single Mu configuration may achieve a Q-factor of approximately 8-12 at sub-6 GHZ frequencies, while the use of double Mu may improve the Q-factor by approximately 1.1×. This enhancement may be especially useful in wideband RF applications where high Q is important for maintaining flat gain response and low noise performance.

Although the layout view 1500 illustrates a front-side inductor implementation, it may also be possible to use backside metal layers and substrate-via connections to implement the inductors in alternative versions of the design. For instance, the inductors may be fabricated on the backside of the wafer and connected through the substrate using through-silicon vias (TSVs) or other deep via structures. Such backside implementations may provide additional isolation from front-side noise sources and allow for more efficient layout density by vertically partitioning passive and active components.

The layout view 1500 may improve performance metrics such as gain flatness, return loss, and noise figure, particularly across a wide frequency range. The inductors may be shaped in an octagonal geometry due to design rule restrictions that prohibit circular inductors. The trace width of the spiral inductor may be approximately 0.9 μm to ensure that the peak Q-factor occurs at or above the target operating frequency. In some examples, aluminum redistribution layers (Al-RDL) may be used as an alternative to ultra-thick copper for cost or integration reasons.

The fully integrated, on-chip matching network, combined with the above described layout architecture and techniques, including implementing the inductors in the top-most ultra-thick metal layers may enable lower series resistance and improved current handling, thereby increasing the quality factor (Q-factor) of the inductors. Further the use of dual ultra-thick metal configurations may further elevate the inductive structures away from the lossy silicon substrate, resulting in reduced substrate energy loss and enhanced magnetic field containment. These improvements may lead to flatter gain, lower noise figure, and enhanced impedance matching across a broad frequency range.

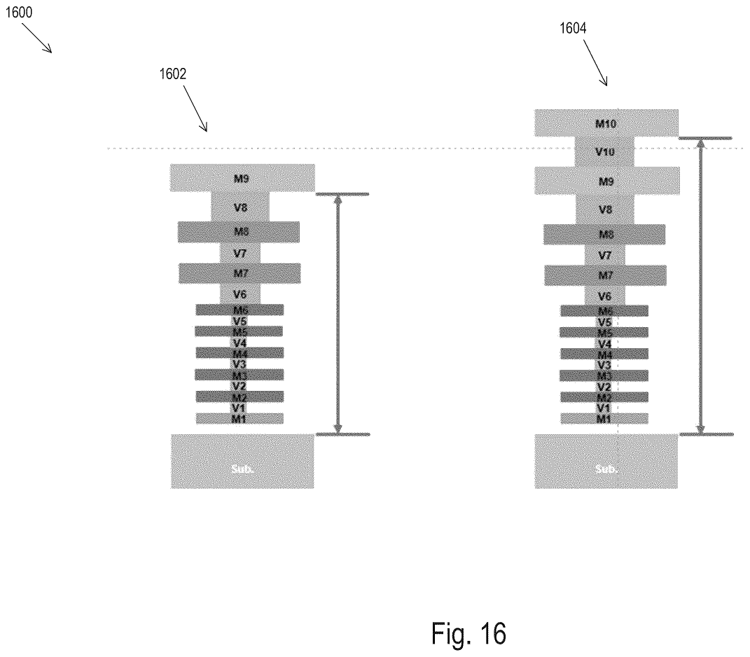

FIG. 16 is a diagram 1600 schematically illustrating a cross-section of two example metal layer stacks used to implement an on-chip low-noise amplifier LNA circuit 104 of FIG. 1. The diagram 1600 shows multiple metal layers formed above a semiconductor substrate, with a baseline metal stack structure 1602 comprising nine metal layers (M1-M9), and a double Mu metal stack structure 1604 comprising ten metal layers (M1-M10), including an additional ultra-thick top metal layer (M10) and corresponding via layer (V10). The LNA circuit and matching network configurations described in FIGS. 2-12 may be implemented using either the baseline metal stack structure 1602 or the double Mu metal stack structure 1604. However, the double Mu metal stack structure 1604 provides advantages, such as enabling inductors or transformers to be implemented farther from the lossy substrate, thereby reducing substrate coupling and improving the Q-factor of the inductive elements. In both configurations, the metal layers are interconnected using vertical vias and are formed on a silicon substrate. The inductors or transformers—such as those shown in FIGS. 15 and 16—may be implemented in the top-most metal layer (e.g., M9 in the baseline case, M10 in the double Mu case), while the intermediate layers may be used for active circuitry and routing interconnects. The double Mu configuration may also support vertically stacked transformer layouts or wider inductor geometries, offering improved magnetic coupling and integration flexibility for wideband RF applications.

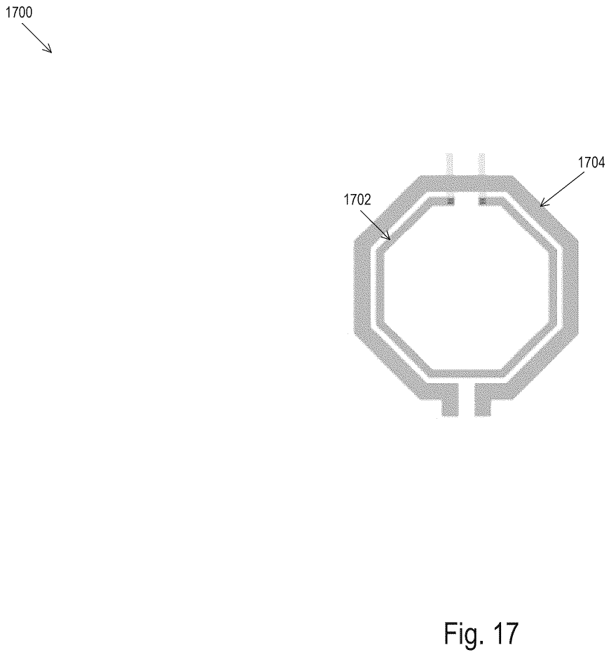

FIG. 17 illustrates a layout view 1700 of another example implementation of the inductors from an input matching network associated with an LNA circuit of FIG. 1. The layout view 1700 demonstrates an alternative configuration in which inductors from the input matching network configurations described herein can be implemented using a transformer-based structure rather than spiral inductors. This layout may serve as a compact alternative to the implementations described in relation to FIG. 15 and may offer area efficiency and enhanced magnetic coupling in certain design contexts.

The layout view 1700 includes components 1702 and 1704, which represent respective implementations of coupled inductive structures. In this example, component 1702 may correspond to a first inductor and component 1704 to a second inductor, together forming a transformer structure. These components may be configured to function similarly to inductors 318 and 320 of the input matching network 304 described in FIG. 3. However, the transformer layout technique may also be used to implement any of the inductive elements found in the matching networks of the various LNA circuits described in FIGS. 1-14, including both differential and single-ended configurations.

In the transformer-based inductor configuration, two or more inductors may be arranged in close proximity and electromagnetically coupled to form a transformer with a defined mutual inductance. This structure may allow for more compact implementations by enabling multi-functionality—such as impedance transformation and phase shifting—within a reduced footprint. In particular, the use of a stacked layout combining ultra-thick metal layers (e.g., M9 or M10) with aluminum redistribution layers (Al-RDL) may enhance Q-factor while allowing for tight inductive coupling. This vertical stacking may also reduce substrate losses and support improved shielding and routing compared to side-by-side spiral configurations.

While the transformer-based inductors shown in FIG. 17 differ in structure from the octagonal spiral inductors described in FIG. 15, they may still be fabricated using similar metal layers, patterning techniques, and shielding strategies. For example, the same double Mu metal process used to raise the inductors away from the lossy substrate may be employed here to improve performance, and the underlying active circuitry may still be placed beneath the transformer structure with optional patterned ground shielding. This may allow the transformer configuration to serve as a drop-in alternative in applications where reduced area, enhanced coupling, or specific impedance characteristics are desired, while still benefiting from the fabrication and integration approaches disclosed herein.

FIG. 18 illustrates a layout view 1800 of an example vertical integration structure for implementing an on-chip low-noise amplifier (LNA) circuit, such as the LNA circuit from FIG. 1. The layout view 1800 is configured to illustrate how various functional elements of the LNA circuit may be distributed across different metal layers in a multi-layer semiconductor process. This layer-based organization may support improved performance, enhanced integration density, and reduced parasitic interference-particularly in wideband RF applications.

The layout includes three general layer regions. Region 1802 represents the bottom metal layers, which may be used for power routing, substrate contacts, and global ground planes. Region 1802 is typically closest to the silicon substrate and may serve as a foundation for supporting analog or digital biasing infrastructure. Region 1804 represents the middle metal layers, which may be used to implement the circuits and interconnects of the LNA core, including transistors, bias resistors, capacitors, and local signal routing. These layers may provide sufficient routing density while maintaining relatively low parasitic resistance and capacitance, which is important for ensuring proper signal integrity at RF frequencies.

Region 1806 represents the top metal layer, which in this implementation is part of a dual ultra-thick metal (DUTM) technology stack. The top metal layer may include one or more ultra-thick copper layers, such as M9 and M10, that are used for fabricating inductors or transformers. Implementing inductive elements in these top-most layers may improve Q-factor by increasing the physical distance from the lossy silicon substrate and by reducing series resistance due to the large conductor thickness. The DUTM layers may also support large-area or high-current structures without significant performance degradation.

Region 1808 represents the circuits and associated interconnects of the LNA circuit, such as the LNA topology illustrated in FIG. 1. These may be placed within the middle layers (e.g., M2-M6) to allow sufficient isolation from the passive components located in the upper layers. The interconnects within this region may be configured to connect the core amplification stage to the matching network components implemented in higher layers.

Region 1810 illustrates an example of a patterned ground shielding (PGS) structure located beneath the inductor or transformer. The PGS may consist of grounded metal mesh or segmented ground planes implemented in one of the intermediate metal layers, such as M6 or M7, and is configured to suppress electromagnetic coupling between the inductor and underlying circuit elements. In this example, the PGS may be used to isolate the inductor from active transistors, reducing substrate noise injection and improving overall signal fidelity. In alternative implementations, different shielding topologies—such as continuous ground planes or differential mesh shielding—may be used depending on layout constraints and frequency range.

Region 1812 represents the inductor or transformer component implemented in the top metal layer. This structure may correspond to any of the spiral inductors described in FIG. 15 or transformer configurations described in FIG. 17. Whether implemented as a single-ended spiral or a magnetically coupled transformer, the top-layer inductor or transformer may take advantage of DUTM stacking, wider trace widths, and reduced substrate interaction to achieve high Q-factors suitable for sub-6 GHZ wideband operation. By vertically isolating the passive matching network components from the active LNA circuitry, the layout view 1800 may provide a compact and scalable approach for integrating RF front-end circuits in advanced process technologies.

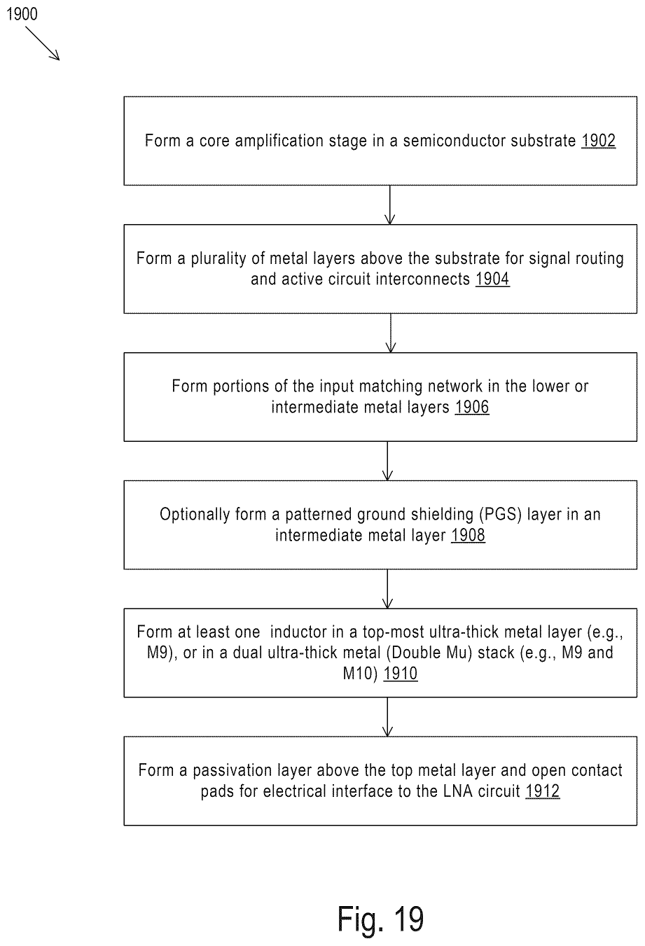

FIG. 19 illustrates an example flow chart diagram 1900 schematically illustrating a method of manufacturing a low-noise amplifier (LNA) circuit with an on-chip input matching network, in accordance with some embodiments. The LNA circuit may include a cascode core amplification stage and an input matching network comprising capacitors and inductors that are fully integrated on-chip. In some embodiments, the LNA circuit is like the amplifier circuit described in FIGS. 2-12, and the layout configuration for the inductors is like those shown in FIGS. 15-17.

At operation 1902, the method includes forming a core amplification stage in a semiconductor substrate. The core amplification stage may include a first transistor and a second transistor in a cascoding configuration. The transistors may be formed using standard CMOS front-end processing techniques, such as implanting wells, defining gate structures, and forming source/drain regions.

At operation 1904, the method includes forming a plurality of metal layers above the substrate. These metal layers may include lower metal layers for signal routing and active circuit interconnects, intermediate metal layers for capacitors and patterned ground shielding, and top metal layers for inductive elements. The number and thickness of metal layers may vary depending on the process node and integration requirements.

At operation 1906, the method includes forming portions of the input matching network comprising capacitors coupled to the core amplification stage. The capacitors may be implemented in the lower or intermediate metal layers, and may be coupled to the gate terminals of the transistors in the core amplification stage.

At operation 1908, the method includes optionally forming a patterned ground shielding (PGS) layer in an intermediate metal layer such that the PGS layer is below the inductors of the matching network. The PGS structure may reduce electromagnetic coupling between the inductor and underlying active circuitry and may be connected to ground using vertical vias.

At operation 1910, the method includes forming at least one spiral inductor in a top-most ultra-thick metal layer (e.g., M9), or in a dual ultra-thick metal (Double Mu) stack (e.g., M9 and M10). The inductor may be configured to reduce package loss and extend bandwidth. In some embodiments, the inductor is implemented using an octagonal geometry with a conductor width selected to ensure a high Q-factor near the operating frequency range.

At operation 1912, the method includes forming a passivation layer above the top metal layer and opening contact pads for electrical interface to the LNA circuit. The finished structure comprises a compact, integrated wideband LNA with an on-chip matching network suitable for high-frequency RF applications.

In one example, a low-noise amplifier (LNA) circuit comprises an input port; a core amplification stage comprising a first transistor and a second transistor forming a cascoding amplifier topology; an output port coupled to a first drain terminal of the first transistor and a second drain terminal of the second transistor; and an input matching network coupled between the input port and the core amplification stage, wherein the input matching network includes: a first capacitor coupled between the input port and a node; a first inductor coupled between a gate bias voltage and the node; a second inductor coupled between the node and a first gate of the first transistor; and a second capacitor coupled between the node and a second gate of the second transistor.

In another example, a radio-frequency (RF) system comprises: an antenna; a quadrature mixer; a differential low-noise amplifier (LNA) circuit with a first input port, a second input port, a first output port and a second output port, wherein the first input port and the second input port are coupled to the antenna and the first output port and the second output port are coupled to the quadrature mixer, wherein the LNA circuit comprises: a core amplification stage comprising a first transistor and a second transistor forming a first side of the differential LNA circuit and a third transistor and a fourth transistor forming a second side of the differential LNA circuit, wherein a first drain terminal of the first transistor and a second drain terminal of the second transistor are coupled to the first output port and a third drain terminal of the third transistor and a fourth drain terminal of the fourth transistor are coupled to the second output port; a first input matching network coupled between the first input port and the core amplification stage, wherein the first input matching network includes: a first capacitor coupled between the first input port and a first node; a first inductor coupled between a first gate bias voltage and the first node; a second inductor coupled between the first node and a first gate of the first transistor; and a second capacitor coupled between the first node and a second gate terminal of the second transistor; and a second input matching network coupled between the second input port and the core amplification stage, wherein the second input matching network includes: a third capacitor coupled between the second input port and a second node; a third inductor coupled between a second gate bias voltage and the second node; a fourth inductor coupled between the second node and a third gate of the third transistor; and a fourth capacitor coupled between the second node and a fourth gate terminal of the fourth transistor.

In a further example, a method for amplifying a radio frequency (RF) signal using a low-noise amplifier (LNA) circuit comprises: receiving, from an antenna, the RF signal at an input port of the LNA circuit, wherein the LNA circuit includes a core amplification stage to amplify the RF signal; matching an output impedance of the antenna to an input impedance of the core amplification stage of the LNA circuit using an input matching network coupled between the input port and the core amplification stage; amplifying the RF signal to generate an amplified RF signal using the core amplification stage; wherein the core amplification stage comprises a first transistor and a second transistor forming a cascoding amplifier topology; and wherein the input matching network includes: a first capacitor coupled between the input port and a node; a first inductor coupled between a gate bias voltage and the node; a second inductor coupled between the node and a first gate of the first transistor; and a second capacitor coupled between the node and a second gate of the second transistor.

In yet another example, a low-noise amplifier (LNA) circuit comprises: an input port; a core amplification stage comprising a first transistor and a second transistor forming a cascoding amplifier topology; an output port coupled to a first drain terminal of the first transistor and a second drain terminal of the second transistor; and an input matching network coupled between the input port and the core amplification stage, wherein the input matching network includes: a first capacitor coupled between the input port and a node; a first inductor coupled between the node and ground in a shunt configuration; a second capacitor coupled between the node and a first gate of the first transistor; and a second inductor coupled between the second capacitor and a second gate of the second transistor.

This disclosure outlines various embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A low-noise amplifier (LNA) circuit comprising:
an input port;
a core amplification stage comprising a first transistor and a second transistor forming a cascoding amplifier topology;
an output port coupled to a first drain terminal of the first transistor and a second drain terminal of the second transistor; and
an input matching network coupled between the input port and the core amplification stage, wherein the input matching network includes:
a first capacitor coupled between the input port and a node;
a first inductor coupled between a gate bias voltage and the node;
a second inductor coupled between the node and a first gate of the first transistor; and
a second capacitor coupled between the node and a second gate of the second transistor;
wherein the core amplification stage, and the input matching network are both implemented on-chip.

2. The LNA circuit of claim 1, further comprising a resistor coupled between the output port and the second gate of the second transistor.

3. The LNA circuit of claim 1, further comprising a source degeneration inductor coupled between a first source terminal of the first transistor and ground.

4. The LNA circuit of claim 1, wherein the first inductor and the second inductor are implemented in one or more top-most ultra-thick metal layers of a semiconductor die, and the first transistor and the second transistor are implemented in one or more metal layers below the top-most metal layers.

5. The LNA circuit of claim 4, further comprising a patterned ground shielding (PGS) structure disposed between the one or more top-most metal layers and the one or more metal layers below, wherein the PGS structure is configured to reduce electromagnetic coupling between the input matching network and the core amplification stage.

6. The LNA circuit of claim 1, further comprising an output matching network coupled between the core amplification stage and the output port, wherein the output matching network comprises:
a third capacitor coupled between the output port and a second node;
a third inductor coupled between the second node and the ground in a shunt configuration;
a fourth inductor coupled between the second node a fourth capacitor; and
the fourth capacitor coupled between the fourth inductor and the first drain terminal of the first transistor and the second transistor.

7. The LNA circuit of claim 1, wherein
the input port is a differential input including a first input port and a second input port and the output port is a differential output including a first output port and a second output port, wherein the input matching network is coupled to the first input port and the output matching network is coupled to the first output port; and
the core amplification stage further comprises a third transistor and a fourth transistor, wherein:
the first output port is coupled to the first drain terminal of the first transistor and the second drain terminal of the second transistor; and
the second output port is coupled to a third drain terminal of the third transistor and a fourth drain terminal of the fourth transistor.

8. The LNA circuit of claim 7, further comprising a second input matching network coupled between the second input port and the core amplification stage and a second output matching network coupled between the core amplification stage and the second output port.

9. The LNA circuit of claim 1, wherein the first transistor is a NMOS transistor, and the second transistor is a PMOS transistor.

10. A radio-frequency (RF) system comprising:
an antenna;
a quadrature mixer;
a differential low-noise amplifier (LNA) circuit with a first input port, a second input port, a first output port and a second output port, wherein the first input port and the second input port are coupled to the antenna and the first output port and the second output port are coupled to the quadrature mixer, wherein the LNA circuit comprises:
a core amplification stage comprising a first transistor and a second transistor forming a first side of the differential LNA circuit and a third transistor and a fourth transistor forming a second side of the differential LNA circuit, wherein a first drain terminal of the first transistor and a second drain terminal of the second transistor are coupled to the first output port and a third drain terminal of the third transistor and a fourth drain terminal of the fourth transistor are coupled to the second output port;
a first input matching network coupled between the first input port and the core amplification stage, wherein the first input matching network includes:
a first capacitor coupled between the first input port and a first node;
a first inductor coupled between a first gate bias voltage and the first node;
a second inductor coupled between the first node and a first gate of the first transistor; and
a second capacitor coupled between the first node and a second gate terminal of the second transistor;
a second input matching network coupled between the second input port and the core amplification stage, wherein the second input matching network includes:
a third capacitor coupled between the second input port and a second node;
a third inductor coupled between a second gate bias voltage and the second node;
a fourth inductor coupled between the second node and a third gate of the third transistor; and
a fourth capacitor coupled between the second node and a fourth gate terminal of the fourth transistor; and
wherein the core amplification stage, the first input matching network and the second input matching network are implemented on-chip.

11. The RF system of claim 10, further comprising a first resistor coupled between the first output port and the second gate of the second transistor and a second resistor couped between the second output port and the fourth gate of the fourth transistor.

12. The RF system of claim 10, further comprising a first source degeneration inductor coupled between a first source terminal of the first transistor and ground and a second source degeneration inductor coupled between a third source terminal of the third transistor and the ground.

13. The RF system of claim 10, further comprising a first output matching network coupled between the core amplification stage and the first output port and a second output matching network coupled between the core amplification stage and the second output port.

14. The RF system of claim 13, wherein the first output matching network comprises:
a fifth capacitor coupled between the first output port and a third node;
a fifth inductor coupled between the third node and the ground in a shunt configuration;
a sixth inductor coupled between the third node a sixth capacitor; and
the sixth capacitor coupled between the sixth inductor and the first drain terminal of the first transistor and the second drain terminal of the second transistor.

15. The RF system of claim 14, wherein the second output matching network comprises:
a seventh capacitor coupled between the second output port and a fourth node;
a seventh inductor coupled between the fourth node and the ground in a shunt configuration;
an eighth inductor coupled between the fourth node an eighth capacitor; and
the eighth capacitor coupled between the eighth inductor and the third drain terminal of the third transistor and the fourth drain terminal of the fourth transistor.

16. The RF system of claim 10, wherein the first transistor and the second transistor are NMOS transistors, and the second transistor and the fourth transistor are PMOS transistors.

17. The RF system of claim 10, wherein the first input matching network and the second input matching network are tuned to match an input impedance of the core amplification stage to an output impedance of the antenna.

18. A method for amplifying a radio frequency (RF) signal using a low-noise amplifier (LNA) circuit, the method comprising:
receiving, from an antenna, the RF signal at an input port of the LNA circuit, wherein the LNA circuit includes a core amplification stage to amplify the RF signal;
matching an output impedance of the antenna to an input impedance of the core amplification stage of the LNA circuit using an input matching network coupled between the input port and the core amplification stage;
amplifying the RF signal to generate an amplified RF signal using the core amplification stage;
wherein the core amplification stage comprises a first transistor and a second transistor forming a cascoding amplifier topology; and
wherein the input matching network includes:
a first capacitor coupled between the input port and a node;
a first inductor coupled between a gate bias voltage and the node;
a second inductor coupled between the node and a first gate of the first transistor; and
a second capacitor coupled between the node and a second gate of the second transistor; and
wherein the core amplification stage and the input matching network are both implemented on-chip.

19. The method of claim 18, further comprising:
matching an output impedance of the core amplification stage of the LNA circuit to an input impedance of a quadrature mixer using an output matching network.

20. The method of claim 19, wherein the output impedance of the antenna, the input impedance of the core amplification stage of the LNA circuit, the output impedance of the core amplification stage of the LNA circuit and the input impedance of the quadrature mixer is 50 ohms.
